(19) United States
(12) Patent Application Publication
(10) Pub. No.: US 2010/0163684 A1
(43) Pub. Date: Jul. 1, 2010

(54) SELF OPENING HINGES

(75) Inventors: Glyn Charles Dando, Farnborough (GB); Alan John Freeman, Farnborough (GB)

Correspondence Address: OLIFF & BERRIDGE, PLC, P.O. BOX 320850, ALEXANDRIA, VA, 22320-4850, US

(73) Assignee: QINETIQ LIMITED, LONDON (GB)

(21) Appl. No.: 12/299,488

(22) PCT Filed: May 24, 2007
(86) PCT No.: PCT/GB2007/001945

§ 371 Date: Nov. 4, 2008

(30) Foreign Application Priority Data
Jun. 6, 2006 (GB) 0611061.3

(51) Int. Cl. B64G 1/44; B64G 1/22; E05D 1/02; H01L 31/042

(52) U.S. Cl. 244/172.6; 16/225; 136/244

(57) ABSTRACT

A self opening hinge comprises a tubular member with a set of circumferentially spaced blades extending longitudinally between opposite end portions. It can be folded by bending the blades to bring the end portions together and when released will naturally return to the straight condition under the spring action of the blades. The blade which will be located on the inside of the fold when the member is in its folded condition is configured with a convex circumferential curvature as viewed from the axis of the member when in its unfolded condition, namely reversed in curvature as compared with the other blades. In this way the stress on the inside blade when the member is folded is reduced as compared with a conventional hinge where all the blades follow a circular tube profile and are concave as viewed from the central axis.

The present invention relates to self opening hinges.

More particularly the invention relates to self opening hinges of a known kind comprising an elongate member with a hinge region comprising a plurality of circumferentially spaced blades extending longitudinally between axially spaced portions of the member whereby the member can be folded by bending of the blades and can resile to its unfolded condition (self open) when released. Hinges of this kind are known for example from U.S. Pat. No. 6,321,503, U.S. Pat. No. 6,374,565 and WO2004/005645 and may be used in collapsible booms, trusses, longerons or other similar structures. One particular field of application for such hinges is in the deployment of instruments, antennas, solar arrays or other such structures in space, where a structure comprising one or more such hinges can be collapsed and packaged to save space during delivery from earth and then released to expand and return accurately and stably to its original shape in orbit.

The known hinges of this kind may be fabricated from several components, where the blades are formed from separate pieces of spring steel or plies of composite material, or more preferably are formed as monolithic members from fibre reinforced polymer composites. Irrespective of their material composition or method of manufacture, however, all the prior art hinges of this kind known to the applicants are based on circular tubular structures, with the profiles of the blades across their respective circumferential extents conforming generally to the tubular portions of the structure which they interconnect. In particular a characteristic of this form is that each blade is configured with a concave circumferential curvature as viewed from the axis of the tube in its unfolded condition. This does, however, impose an undesirable design limitation on hinges of this kind, as will now be explained.

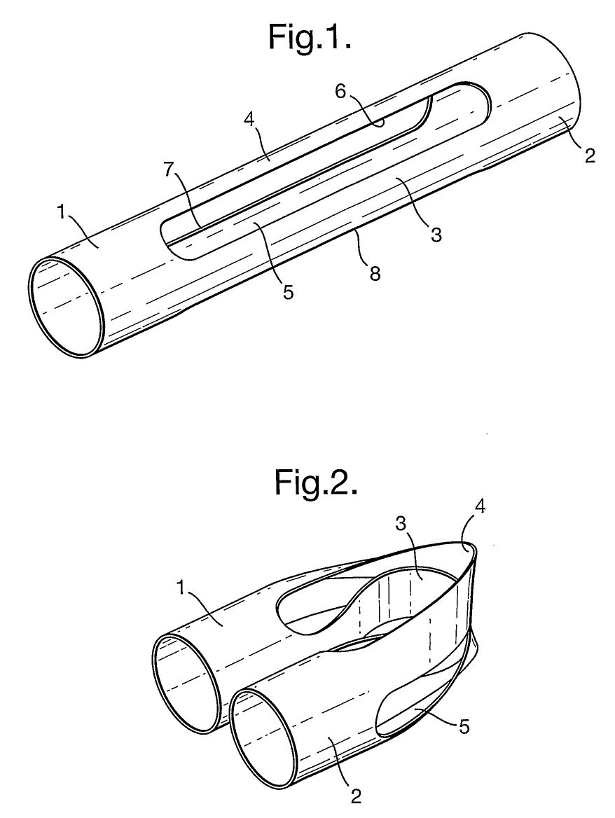

A typical prior art hinge of the kind described above is shown in FIGS. 1 and 2. With reference to FIG. 1, which shows the hinge in its unfolded condition, it comprises a tube with end portions 1 and 2 joined by a plurality, in this case three, of longitudinal blades 3, 4, 5 formed by cutting the same number of longitudinal slots 6, 7, 8 through the tube wall. The blades 3, 4, 5 each have a circumferential curvature defined by the radius of the tube and have sufficient stiffness to maintain the hinge in its unfolded condition under the service conditions for which it is designed. To fold the tube, however, it is subjected to a bending force, the inward direction of which is generally aligned with one of the blades, say blade 3, the effect of which is to buckle (flatten) the central regions of the blades and bend the same into the folded condition of the hinge depicted in FIG. 2, in which the end portions 1 and 2 of the tube can be brought together so far as to lie in a substantially parallel relationship if desired. It will be seen that in this condition the blade 3 is located on the inside of the fold with the blades 4 and 5 wrapped around the blade 3 on the outside of the fold. The hinge can be held in this condition by any suitable means for so long as is required by the service to which the device is put, but when released can spring back to its FIG. 1 condition by the elasticity of the deformed blades.

While prior art hinges of the kind described above have been found to function satisfactorily when based on tubes of, say, 40 mm diameter or larger, it is desirable particularly for space applications to be able to produce such hinges of smaller diameter and lighter weight. As the diameter is reduced the circumferential curvature of the blades increases and so does the stress imparted to the blades when the hinge is folded—most particularly in the case of the blade(s) on the inside of the fold (i.e. blade 3 in the example of FIG. 2) which is necessarily bent back against the direction of its natural curvature, and this can lead to failure of such blade(s). This problem is exacerbated when the hinge is made from a fibre reinforced polymer composite, which is much preferred to fabrication with spring steel blades on cost and weight grounds, due to the wall thickness which is required to maintain a sufficient degree of isotropy in the structure.

The present invention seeks to alleviate the above-described problem associated with prior art hinges and accordingly in one aspect resides in a self opening hinge comprising an elongate member with a hinge region comprising a plurality of circumferentially spaced blades extending longitudinally between axially spaced portions of the member whereby the member can be folded by bending of said blades and can resile to its unfolded condition when released; and wherein one or more said blades, located on the inside of the fold when the member is in its folded condition, is configured with a convex circumferential curvature as viewed from the axis of the member when in its unfolded condition.

By effectively reversing the sense of the natural curvature of the inner blade(s) of the hinge in this way the overall stress on the same when folded can be much reduced as compared with a conventional hinge of equivalent cross-sectional dimension, meaning that smaller hinges can be successfully constructed particularly in fibre reinforced polymer composite materials, and/or that a greater wall thickness can be employed for the same cross-sectional dimension, leading to members of greater stiffness in the unfolded condition.

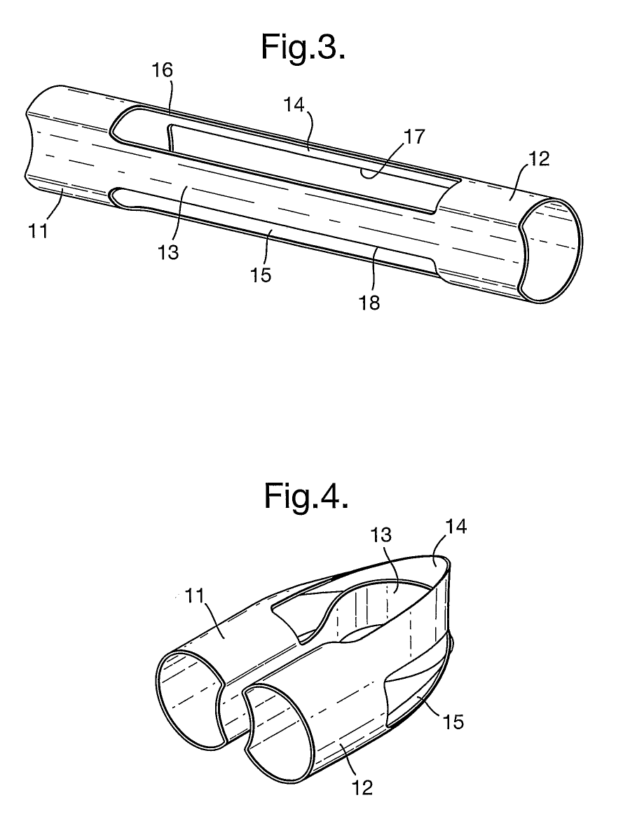

These and other aspects and features of the present invention will now be more particularly described, by way of example, with reference to FIGS. 3 to 5 of the accompanying drawings in which:

FIG. 3 shows one embodiment of a hinge according to the invention in its unfolded condition;

FIG. 4 shows the hinge of FIG. 3 in its folded condition; and

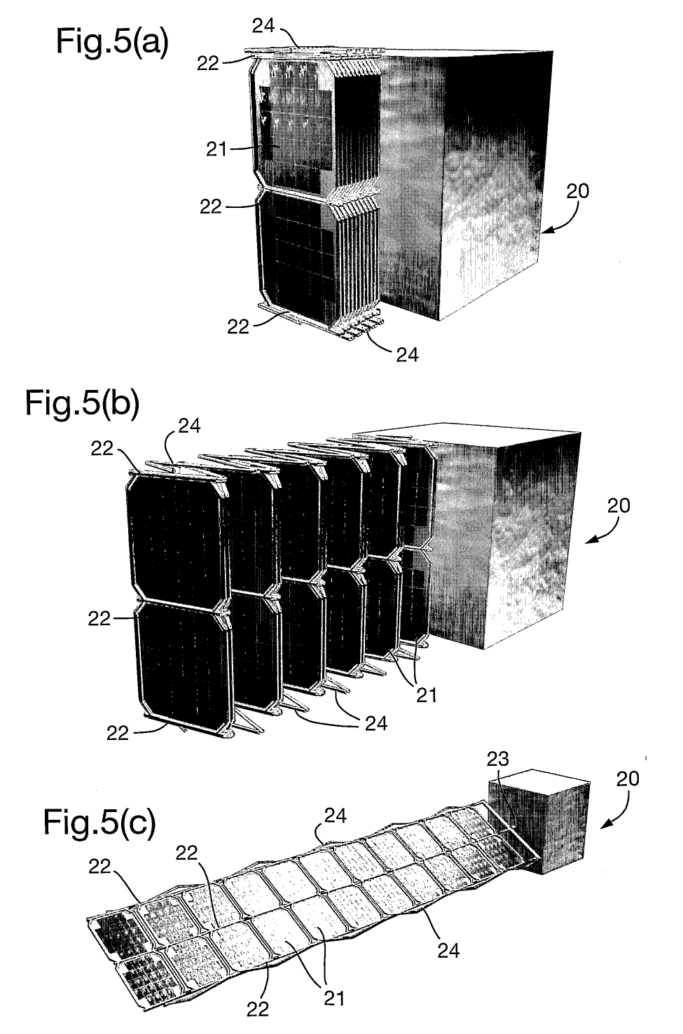

FIGS. 5(a), (b) and (c) illustrate the deployment of a solar array from a satellite by means of booms equipped with hinges according to the invention.

Referring to FIGS. 3 and 4 the illustrated hinge comprises a tube preferably of carbon fibre reinforced polymer composite material, with end portions 11 and 12 joined by three longitudinal blades 13, 14, 15 formed by cutting longitudinal slots 16, 17, 18 through the tube wall. The blades 14 and 15 both have a circumferential curvature which is concave as viewed from the axis of the tube and in this respect are similar to the blades of the prior art hinge of FIG. 1. In accordance with the invention, however, the blade 13 is configured with a convex circumferential curvature as viewed from the axis of the tube. The stiffness of such a tube in its unfolded condition can equate to that of its FIG. 1 counterpart or, as previously explained, may actually be greater for a tube of the same cross-sectional dimension since a greater wall thickness can be employed.

To fold the hinge of FIG. 3 it is subjected to a bending force the inward direction of which is generally aligned with the blade 13. Like the prior art example of FIG. 1, this has the effect of buckling (flattening) the central regions of the blades and bending the same into the folded condition of the hinge depicted in FIG. 4, in which the end portions 11 and 12 of the tube can be brought together so far as to lie in a substantially parallel relationship if desired. Also it will be seen that the blade 13 is located on the inside of the fold with the blades 14 and 15 wrapped around the blade 13 on the outside of the fold. In this case, however, the blade 13 at the inside of the fold will be subject to significantly less stress than the corresponding blade of the FIG. 1 example because it does not have to be bent back against its natural concavity, with the attendant advantages previously explained. When released the hinge can spring back from its FIG. 4 to its FIG. 3 condition by the elasticity of the deformed blades, similarly to the prior art.

By way of example, a hinge substantially as illustrated in FIG. 3 with a maximum cross-sectional dimension (diameter of concave segment) of 13 mm and constructed from a two ply carbon reinforced polymer composite laminate with a total wall thickness of 0.2 mm has been modelled and shown to achieve a reduction in the overall stress in the inner blade when folded of a factor of approximately two in comparison with a prior art hinge of equivalent dimensions.

The hinge of FIG. 3 is of monolithic structure and formed from a tube having the illustrated concave/convex circumferential profile throughout its length. It is not necessary for the end portions 11 and 12 to reproduce the profile of the bladed hinge region, however, and they may generally be of any desired form, whether hollow or solid, and configured as required e.g. for connection into a larger structure to be actuated or deployed by unfolding of the hinge. Neither is it essential that hinges according to the invention, while elongate in form, are rectilinear as illustrated in FIG. 3, and other embodiments may be configured with a degree of axial curvature in the unfolded condition if required for particular purposes.

Furthermore, while the illustrated arrangement of three blades—two concave (14, 15) and one convex (13) generally equispaced around the circumference of the hinge—is convenient and effective, other embodiments may comprise other numbers of blades, e.g. two, four, five or even more, provided that the blade or blades which are located on the inside of the fold have the characteristic reverse circumferential curvature (convex as viewed from the axis) as compared to the remainder. For example a two bladed hinge will have one convex blade and one concave blade; a four bladed hinge may have two convex blades and two concave blades; a five bladed hinge may have two convex blades and three concave blades, and so on. The relative circumferential widths of the blades and intervening slots may be selected to determine the stiffness of the unfolded hinge—the wider the blades for a given size of hinge the stiffer it will be in the unfolded condition but the more the blades will be stressed when folded. The profile of the blades as determined by the profile of the slots such as 16, 17, 18 is also open to variation if desired, as is known e.g. from U.S. Pat. No. 6,321,503, although the generally rectangular form illustrated in FIG. 3 is convenient and effective.

Hinges as described above may be used in various applications, including those suggested in U.S. Pat. No. 6,321,503, although they are of particular advantage where hinges of small size are required. One example is in self opening toys. Another is the deployment in space of solar arrays for the supply of electrical energy to small (e.g. less than 500 kg) satellites where weight is at an absolute premium.

An example of the latter is illustrated in FIGS. 5(a) to (c). In these Figures a satellite notionally indicated at 20 is equipped with a deployable solar array comprising a plurality (in this case eleven) of panels 21 covered with photovoltaic cells. In the deployed condition of FIG. 5(c) the panels are oriented one beside the next in a common plane and supported by three booms 22 which are respectively attached to each panel along its opposite side edges and along its median. The booms 22 extend from a pivot 23 on the satellite by which the array can be turned to achieve the best angle of incidence to the sun. The satellite is however initially delivered into orbit with the panels 21 in the contracted condition shown in FIG. 5(a). For this purpose each boom 22 is formed as a continuous tube with eleven hinge regions spaced along its length. These hinges are positioned at the junctions between successive panels 21 and between the innermost panel and the satellite, and are each of the kind described above with reference to FIGS. 3 and 4 with the reversed curvature blades such as 13 alternating in circumferential location so that the entire boom can be folded in zig-zag fashion to place the panels 21 in a collapsed parallel stack as illustrated in FIG. 5(a). The panels are latched in this position (by means not shown) until delivered into orbit whence the latch is released and the booms 22 are allowed to unfold under the spring action of their respective hinge regions, thus deploying the array in the sequence indicated by FIGS. 5(a), (b) and (c). A “lazy tongs” mechanism 24 is also provided along opposite edges of the array to synchronise the unfolding of the three booms 22, but the whole of the motive power for the deployment is provided by the energy stored by the previous folding of the hinge regions of the booms.

1. A self opening hinge comprising an elongate member with a hinge region comprising a plurality of circumferentially spaced blades extending longitudinally between axially spaced portions of the member whereby the member can be folded by bending of said blades and can resile to its unfolded condition when released; and wherein one or more said blades, located on the inside of the fold when the member is in its folded condition, is configured with a convex circumferential curvature as viewed from the axis of the member when in its unfolded condition.

2. A hinge according to claim 1 wherein said member comprises a tube with a plurality of slots through its wall, the material between such slots comprising said blades.

3. A hinge according to claim 1 comprising one said blade configured with a convex circumferential curvature and two blades configured with a concave circumferential curvature, as viewed from the axis of the member when in its unfolded condition.

4. A hinge according to claim 1 comprising one said blade configured with a convex circumferential curvature and one blade configured with a concave circumferential curvature, as viewed from the axis of the member when in its unfolded condition.

5. A hinge according to claim 1 comprising two said blades configured with a convex circumferential curvature and at least two blades configured with a concave circumferential curvature, as viewed from the axis of the member when in its unfolded condition.

6. A hinge according to claim 1 wherein said member is of monolithic form and composed of a fibre reinforced polymer composite material.

7. A hinge according to claim 1 wherein said hinge region has a maximum cross sectional dimension not exceeding 40 mm in the unfolded condition.

8. An array of solar panels interconnected by one or more booms comprising a plurality of self opening hinges according to claim 1, whereby said array can be contracted by folding of said hinges and can be deployed by the resilience of said hinges when released.

9. An array according to claim 8 wherein the or each said boom comprises successive said hinge regions of which the respective said blade(s) configured with a convex circumferential curvature (as viewed from the axis of the boom when in its unfolded condition) alternate in circumferential location whereby the boom can be folded in zig-zag fashion.

10. A satellite equipped with a solar array according to claim 8.
